(19) United States
(12) Patent Application Publication
(10) Pub. No.: US 2023/0261673 A1
(43) Pub. Date: Aug. 17, 2023

(54) Machine Learning Based Codec

(71) Applicant: Zibra AI, Inc., Lewes, DE (US)

(72) Inventor: Vladyslav Zavadskyi, Kyiv (UA)

(21) Appl. No.: 18/168,932

(22) Filed: Feb. 14, 2023

Related U.S. Application Data
(60) Provisional application No. 63/310,562, filed on Feb. 15, 2022.

(51) Int. Cl. H03M 7/30

(52) U.S. Cl. CPC H03M 7/70

(57) ABSTRACT

By one approach, these teachings provide for a data compression apparatus comprising a memory having data to be compressed comprising at least one of spatial data and spatio-temporal data stored therein and a control circuit that operably couples to that memory. The control circuit can be configured to access the data to be compressed in the memory and compress that data to provide compressed data. By one approach, the latter comprises subdividing the data to be compressed into a plurality of subspaces and then using an initialization scheme to construct at least one compressed representation of the data to be compressed.

### RELATED APPLICATION(S)

This application claims the benefit of U.S. Provisional application No. 63/310,562, filed Feb. 15, 2022, which is incorporated by reference in its entirety herein.

### TECHNICAL FIELD

These teachings relate generally to data compression.

### BACKGROUND

Data can be represented using any of a variety of data formats. It is often prohibitively expensive to store raw data, so most representations employ coding or compression to reduce data size. Depending on the specifics of the data and its usage, those coding methods may vary drastically.

Handling volumetric data has been notoriously difficult historically, as it has cubical memory complexity. The difficulty increases when animation is present that contains many frames of cubically complex data. This creates bottlenecks in transmitting, storing, and accessing the data as one would need to deliver the data from storage device to the processing device, requiring high memory bus bandwidth, and then storing the data in RAM or VRAM, requiring high capacity.

Naïve ways of reducing the size of such data include bit level compression such as Huffman coding, which does not sufficiently alleviate the problem: the size of the data compressed in this way is still large, leaving the problems of transmission, storage, and RAM/VRAM capacity insufficiently addressed. It also does not allow extracting the data only where one needs it. Instead the whole array must be decoded to access only a single element, which can also be prohibitively expensive in terms of computation and/or unsatisfactory in terms of temporal requirements.

Some methods, such as OpenVDB, employ hierarchical data structures such as octrees and exploit the spasticity of the data heavily. Such compression is lossless and much better in terms of memory complexity then storing the raw field, but it still has a considerable memory footprint and high data access latency due to complex flow control, which prohibits its use in applications where those are critical, such as real-time graphics or games.

Other recent methods, such as NeuralVDB, exploit patterns in data found via machine learning to compress it with losses, reducing memory footprint by a large margin, but still must deal with complex flow control and high computational costs of the decompression, once again limiting its use in real-time scenarios.

### BRIEF DESCRIPTION OF THE DRAWINGS

The above needs are at least partially met through provision of the machine learning based codec described in the following detailed description, particularly when studied in conjunction with the drawings, wherein:

FIG. 1 comprises a block diagram as configured in accordance with various embodiments of these teachings;

FIG. 2 comprises a block diagram as configured in accordance with various embodiments of these teachings; and

FIG. 3 comprises a block diagram as configured in accordance with various embodiments of these teachings.

Elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present teachings. Also, common but well-understood elements that are useful or necessary in a commercially feasible embodiment are often not depicted in order to facilitate a less obstructed view of these various embodiments of the present teachings. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein. The word “or” when used herein shall be interpreted as having a disjunctive construction rather than a conjunctive construction unless otherwise specifically indicated.

### DETAILED DESCRIPTION

Generally speaking, these teachings can serve to provide a machine learning based codec that can compress data (including spatial or spatio-temporal data) without regard to the specifics of the data (at least from the user's standpoint) while providing compression rates, quality preservation, and data access costs that are considerably improved compared to at least most prior art approaches.

By one approach, these teachings provide for compression of arbitrary scalar or vector fields into a compact representation. These teachings can provide for subdividing the original space upon which this field is defined into a grid of subspaces, which optionally can be sparse. Gradient descent can then be employed to find a set of parameters that represent the fields for each given subspace. Those parameters can then be interpolated (interpolation coefficients and indices being the function of coordinates in space) so as to combine information stored in each subspace to be able to query the field at any given point of space or space-time. The latter can then be passed through a simple, in terms of Kolmogorov complexity, algorithm (for example, the algorithm may comprise only a nonlinear function applied to the vector output of interpolation superseded by a weighted sum of the outputs). The resulting representation can be continuous and differentiable on the whole support domain.

By one approach, these teachings provide for a data compression apparatus comprising a memory having data to be compressed comprising at least one of spatial data and spatio-temporal data stored therein and a control circuit that operably couples to that memory. The control circuit can be configured to access the data to be compressed in the memory and compress that data to provide compressed data. By one approach, the latter comprises subdividing the data to be compressed into a plurality of subspaces and then using an initialization scheme to construct at least one compressed representation of the data to be compressed.

By one approach, the data to be compressed comprises single channel three-dimensional volume data. If desired, the data to be compressed may comprise a plurality of multiple channels of temporal volumetric data.

By one approach, the compressed data has an SDF quality average of at least 0.96 as measured by the F1 metric in points near the surface and 0.0006 MAE (mean absolute error) measured in points throughout the volume. As another example, the data to be compressed may comprise Signed Distance Fields (SDF), where the compressed data represents an average compression ratio exceeding ×15 as compared to a volumetric grid of field's values needed to achieve the same quality. As another example, the data to be compressed can comprise visual effects (VFX) data, where the compressed data represents an average compression ratio exceeding ×10 and compression quality of at least 40 as measured with PSNR.

By one approach, the aforementioned optimization algorithm employs, at least in part, gradient descent.

By one approach, the aforementioned control circuit is further configured to use an optimization algorithm to optimize at least one (or both) of the compressed representation and parameters of a function that retrieves original data from the compressed representation by minimizing errors between predicted and actual results to thereby identify sets of parameters that each represent a corresponding one of the plurality of subspaces.

By yet another approach, the aforementioned control circuit is further configured to use a function to recover original data from the compressed representation, wherein the function comprises at least one of a parametrized function and a non-parametrized function.

These teachings can be used in various application settings including, but not limited to, image, video, and three-dimensional model representation, compressing and rendering volumetric effects, estimating or compressing global illumination, shadows, and/or approximation of three-dimensional point-to-object physical interactions through an approximation of a three-dimensional model's signed distance field.

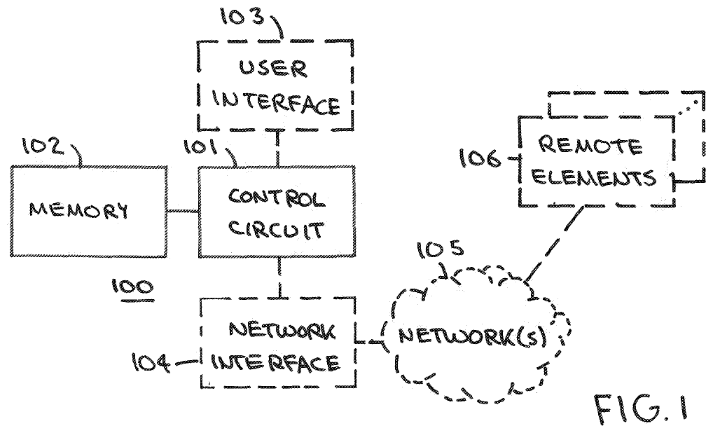

These and other benefits may become clearer upon making a thorough review and study of the following detailed description. Referring now to the drawings, and in particular to FIG. 1, an illustrative apparatus 100 that is compatible with many of these teachings will be presented.

In this particular example, the enabling apparatus 100 includes a control circuit 101 that can serve, at least in part, as a machine learning based codec. Being a “circuit,” the control circuit 101 therefore comprises structure that includes at least one (and typically many) electrically-conductive paths (such as paths comprised of a conductive metal such as copper or silver) that convey electricity in an ordered manner, which path(s) will also typically include corresponding electrical components (both passive (such as resistors and capacitors) and active (such as any of a variety of semiconductor-based devices) as appropriate) to permit the circuit to effect the control aspect of these teachings.

Such a control circuit 101 can comprise a fixed-purpose hard-wired hardware platform (including but not limited to a central processing (CPU) or graphics processing unit (GPU) of a general purpose computer, a deep learning accelerator (such as TPU), an application-specific integrated circuit (ASIC) (which is an integrated circuit that is customized by design for a particular use, rather than intended for general-purpose use), a field-programmable gate array (FPGA), and the like) or can comprise a partially or wholly-programmable hardware platform (including but not limited to microcontrollers, microprocessors, and the like). These architectural options for such structures are well known and understood in the art and require no further description here. This control circuit 101 is configured (for example, by using corresponding programming as will be well understood by those skilled in the art) to carry out one or more of the steps, actions, and/or functions described herein.

In this illustrative example the control circuit 101 operably couples to a memory 102. This memory 102 may be integral to the control circuit 101 or can be physically discrete (in whole or in part) from the control circuit 101 as desired. This memory 102 can also be local with respect to the control circuit 101 (where, for example, both share a common circuit board, chassis, power supply, and/or housing) or can be partially or wholly remote with respect to the control circuit 101 (where, for example, the memory 102 is physically located in another facility, metropolitan area, or even country as compared to the control circuit 101). It will also be understood that this memory 102 may comprise a plurality of physically discrete memories that, in the aggregate, store the pertinent information that corresponds to these teachings.

In addition to data to be compressed, this memory 102 can serve, for example, to non-transitorily store the computer instructions that, when executed by the control circuit 101, cause the control circuit 101 to behave as described herein. (As used herein, this reference to “non-transitorily” will be understood to refer to a non-ephemeral state for the stored contents (and hence excludes when the stored contents merely constitute signals or waves) rather than volatility of the storage media itself and hence includes both non-volatile memory (such as read-only memory (ROM) as well as volatile memory (such as a dynamic random-access memory (DRAM).)

By one optional approach, the control circuit 101 operably couples to a user interface 103. This user interface 103 can comprise any of a variety of user-input mechanisms (such as, but not limited to, keyboards and keypads, cursor-control devices, touch-sensitive displays, speech-recognition interfaces, gesture-recognition interfaces, and so forth) and/or user-output mechanisms (such as, but not limited to, visual displays, audio transducers, printers, and so forth) to facilitate receiving information and/or instructions from a user and/or providing information to a user.

In another optional approach, in lieu of the foregoing or in combination therewith, the control circuit 101 operably couples to a network interface 104. So configured the control circuit 101 can communicate with remote elements 106 via one or more communications/data networks 105. Network interfaces, including both wireless and non-wireless platforms, are well understood in the art and require no particular elaboration here.

By one approach, these teachings can be viewed as a codec having generally three main components, these being a feature volume, a field regressor, and a feature volume construction algorithm. By one approach, feature volume is optimized in a fast manner to represent the field in compressed form, while the field regressor capability can be used to recover the original field values from that representation.

The aforementioned feature volume can be represented as an N+1-dimensional array of parameters where N is the dimensionality of the original data (for example, N=3 for volumetric data and N=2 for a two-dimensional image). The one extra dimension (i.e., that “+1”) stores compressed features of the local region. By one approach, the parameters stored in the feature volume represent compressed original volumetric data and can be found using the optimization algorithm described herein.

If desired, the N dimensions can be flattened into one dimension, or can be reshaped in any other way in order to use and leverage, for example, lookup tables, trees, or other access data structures. Also, if desired, these feature volumes may be sparse as in some application settings it may not be necessary or useful to store all the regions, in which case only regions of interest (for example, near the surface of a depicted object or only in the presence of non-zero field values) might be stored. Also, if desired, different quantization techniques may be applied to further reduce the memory footprint.

The aforementioned field regressor can comprise, by one approach, a function of the feature volume parameters that return the original field values, reducing, expanding or keeping the same number of dimensions as of those of the local regions feature vectors while transforming the feature vector data to arrive at a field's value in a particular point of interest. The field regressor may be implemented as a neural network, an affine transformation, a linear combination, or any other useful function as desired. By one approach, the field regressor may decompress one point per query or more than one point per query (for example, some specific multi-point region of the field of interest).

By one approach, interpolation may be followed directly with a nonlinear function which can, in at least some application settings, add complexity and allow values to change in nonlinear fashion inside one primitive subspace of the interpolated grid. From a neural network standpoint, the latter can be viewed as approximating an arbitrary number of neural network layers that precede the field regressor as described here, thus enabling number of subspaces needed to guaranty good quality of compression to be as minimal as may be reasonably possible. For example, the result can be as minimal as merely a (weighted) sum of the activated features.

Such non-linear function may or may not be used as desired. In at least some application settings, however, eschewing its use may lead to less favorable results.

Interpolation used to obtain feature vector of a concrete point or region may be of any order, precise or approximated (zeroth order too, nearest-neighbor interpolation de facto means simply taking a single nearest value). Interpolation may be parametrized, where the parameters of the interpolations are themselves subject to optimization.

By one approach, the interpolation function is the only subject of optimization with fields values being obtained directly by sampling the stored field values using advanced interpolation.

By one approach, the field regressor uses either the static weighted sum of the interpolated features or a dynamic weighted sum, where the weights can be interpolated using a separate volume or at least volume that can be viewed as separate, as well as the same volume subjected to a different transformation. In former cases, weights can also be subjects to linear or non-linear transformations.

If the field regressor function has parameters or if there is more than one regressor functions employed a clustering algorithm of choice may be used to assign a set of parameters or a particular function to each concrete subspace. Such clustering algorithm may use as a metric the similarity of subspace's field values or its representation (obtained via one of the initialization schemes described below or via any other method, such as a separate neural network) with function's parameters. In the case where function parameters can't be known beforehand, one may use, for example, K-nearest neighbors or farthest point sampling in the similarity metric space. The list of clustering algorithms outlined is not by any means comprehensive and those skilled in the art may use other clustering algorithms to achieve the same result.

In some cases, it may be useful to accompany field values with a mask, especially when the field data comprises non-negligible high frequencies. Then a separate feature volume (or a feature volume that can be viewed as separate, as well as the same volume subjected to a different transformation) can be used to regress mask values by which the regressed field values are masked. It can also be viewed as a dynamic weighting setup as described herein, albeit with one or more specific activation functions being applied (such as, but not limited to logistic function or simple binary thresholding).

These teachings will also support using regressed values with a displacement field for query points to thereby shift the query points into a different region of the feature volume in order to obtain better reconstruction quality. After sampling in a shifted location, the field regressor can be applied to sampled feature vectors (or, if desired, no use of the field regressor may occur in these regards when, for example, a feature volume consists of (possibly modified) fields values).

The aforementioned feature volume construction algorithm may include (optionally) applying an optimization algorithm or a combination of such preceded by an initialization scheme. These teachings will accommodate various initialization schemes including, but not limited to, random initialization, field value initialization, template initialization, neural network initialization, decomposition, and so forth as desired. By one approach, an initialization scheme may perform no optimization per se (notwithstanding that such an approach might employ an iterative approach).

The aforementioned random initialization can comprise obtaining initial parameters by randomly drawing a number with a probability defined by a particular (parameterized or not) statistical distribution.

The aforementioned field value initialization can comprise enabling usage of ground truth field values, or any information that could be derived (such as field's gradient, divergence, Laplacian, and so forth) to construct a feature volume. For example, the volume feature may consist only of field values, which field values may be one or more of the channels in the volume feature, where other channels are initialized using a different technique of choice.

Another example would be using the field's gradient in sampled points inside each subspace to update corresponding subspace's parameters by routing the updates to the most aligned feature channel. Other initialization schemes using values of one or more fields may be used as well as desired.

The aforementioned template initialization can comprise having a template database of features and initializing each feature vector in a corresponding volumetric grid by selecting the most similar feature vector from the template database. In this case, a similarity measure can be a function of how similar a local field is produced when decoded, as compared to an original field in the vicinity.

The aforementioned neural network initialization can comprise using a neural network to obtain feature vectors from the samples of local field regions.

The aforementioned decomposition initialization can comprise using a decomposition algorithm of choice such as, for example, the Singular Value Decomposition (SVD) algorithm. (The SVD algorithm decomposes a matrix into three separate matrices, i.e., a unitary matrix, a diagonal matrix, and another unitary matrix. These matrices represent different aspects of the original matrix, and the process of decomposition allows for a more efficient representation of the data and can be used for various purposes, such as data compression, matrix inversion, and dimensionality reduction.) Such an approach can serve to decompose the original data and, potentially, reduce the dimensionality of the data, obtaining the features for the feature volume as well as the weights of the first (and possibly the only) layer of the field regressor, when implemented as a neural network.

The initialization scheme may be a combination of the aforementioned schemes, including, but not limited to, initializing different channels of feature volume using different schemes, using different schemes in different subspaces, applying schemes in consecutive order, and so forth. In combination with other schemes, constant initialization may be used (i.e. when the whole feature channel(s) is initialized, locally or globally, with a constant value).

The aforementioned optimization algorithm can be any of a variety of functions that change parameters to improve a defined objective function value. The present teachings are differentiable, and can use a variation of stochastic gradient descent, but other methods may also be used, such as evolutionary algorithms, annealing, and so forth. If desired, one optimization algorithm may be coupled with others interchangeably to improve convergence speed or to converge to a better optimum. Other techniques may be used, such as applying an exponential moving average to the trainable parameters. If the feature volume is to be quantized as mentioned in paragraph 0026 it is advisable to use quantization aware optimization to achieve better results.

An illustrative training pipeline that accords with many of these teachings for a corresponding neural network will now be described. Although these teachings make use of iterative optimization, modern hardware can typically complete the optimization in only a few seconds or less. This speed is owing, at least in part, to providing for only a minimal setup of the aforementioned field regressor function.

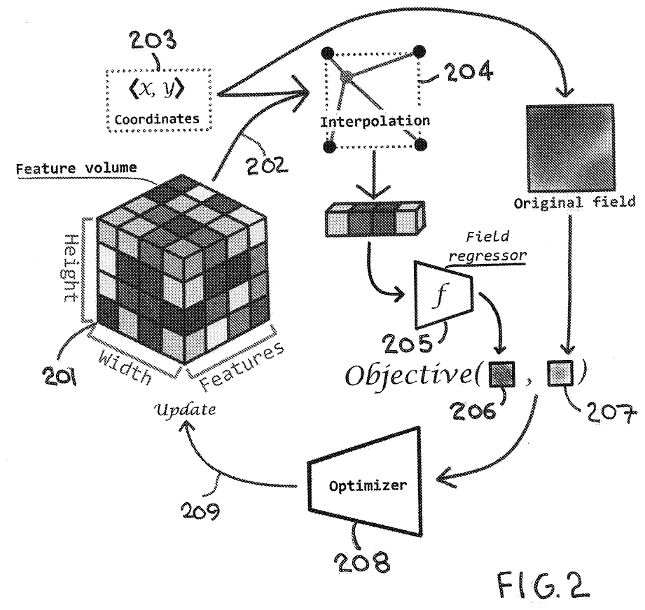

In this illustrative example, and referring to FIG. 2, the training pipeline begins by defining a finite subspace 201 of interest to compress. The pipeline then provides for initializing the feature volume parameters using at least one of the initialization schemes described above (or, if desired, an alternative initialization approach). By one optional approach, these teachings will accommodate now initializing the parameters of the regressor function (if that function has any parameters that will benefit from initializing).

The pipeline can then provide for sampling (as denoted by reference numeral 202) a number of points 203 inside of the already-defined subspace and calculating ground truth field values therein. The latter can include calculating both vector and/or scalar field values. A scalar field will be understood to comprise a function of coordinates in space where the value at each point is scalar. A vector field will be understood to comprise a function of coordinates in space whose value at each point is a vector. For computer graphics applications, by way of example, it may be a surface material characteristic value at a point, a translucency/density value, emissivity value, temperature value, (signed) distance value and so forth.

The pipeline then provides for calculating the corresponding decompressed value given the feature volume's parameters, the field regressor function, and the points' coordinates as established above. The pipeline can then interpolate 204 between feature volume vectors in the neighborhood of a particular sampled point and use the feature vector as input to the field regressor function 205 to obtain field values in that point. As stated above, one such regressor may be a simple nonlinearity and a weighted sum of the nonlinearity output. One example of such a regressor is Leaky ReLU (Rectified Linear Unit). Leaky ReLU is a variant of the standard ReLU activation function used in neural networks. The standard ReLU activation function returns 0 for negative input values and the input value itself for positive input values, whereas Leaky ReLU introduces a small negative slope for input values below zero. This is useful when initialization returns whole subspaces of negative values, which after classical ReLU would be set to zero and would not be differentiable in those regions, thus couldn't be optimized using gradient descent, thus wasting parameter budget. It's worth noting that ReLU also could be used, in such case the initialization scheme could be adjusted to prevent the aforementioned situation. These teachings will accommodate other approaches in the foregoing regards as desired.

The pipeline then provides for calculating the error (which is an objective function value) between the field regression outputs 206 and ground truth field values 207 for each point.

At this point, the pipeline provides for effecting one iteration step of the optimization process 208, as defined by the particular optimization algorithm of choice. This iteration will update the parameters of the feature volumes (and, optionally, those of the field regressor if it has any).

The above-described steps, from the sampling of points within a subspace through the iteration of the optimization process, can be repeated over and over again until the process yields a result 209 that represents convergence to an acceptable objective function value. Those skilled in the art will understand that what constitutes an “acceptable” result can be quite specific to the objective function of choice as well as the nature of the field. What constitutes being acceptable may also vary depending on the set of hyperparameters that are chosen (for example, the number of subspaces, or feature vector's dimensionality). In lieu of the foregoing, or in combination therewith, these teachings will also accommodate using a fixed number of iteration steps that the user expects to provide a good trade off between speed and quality. By yet another approach, and again in lieu of the foregoing or in combination therewith, these teachings will accommodate stopping upon detecting convergence (i.e., when the objective function value does not change (by some selected margin) for some predetermined number of iterations). The stopping condition may also include reaching some target metric level, exceeding allowed optimization time, may be a combination of any of the above or any other condition relevant to the particular setting of the use of the method.

The optimization step may be omitted completely if the initialization scheme is sufficient at providing a feature volume of adequate quality. In such a case, the initialization scheme should also provide regressor parameters if the field regressor is a parametrized function.

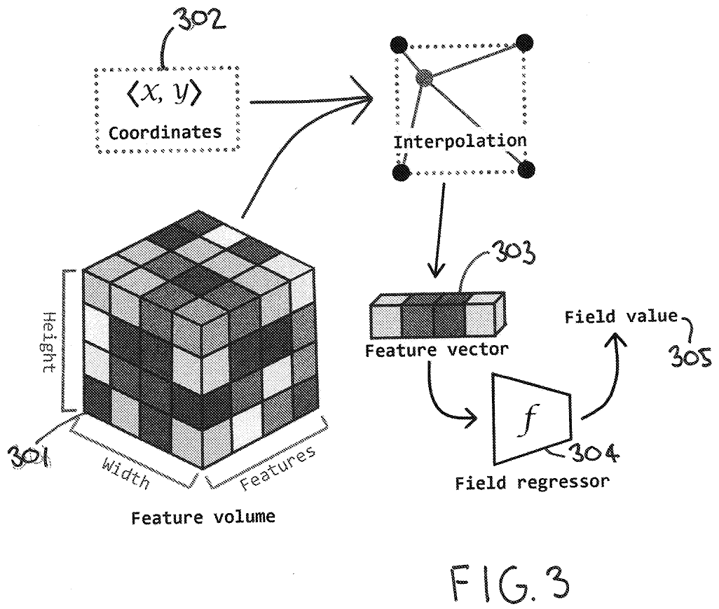

An inference pipeline will now be described with reference to FIG. 3. It will be appreciated that execution of this inference pipeline can be as fast as merely sampling a value from a float32 grid in a standard graphics pipeline, or even in some cases faster, due to better memory alignment and more cache hits provided by the smaller size of the representation.

The inference pipeline can begin by accessing the feature volume 301 obtained as a result of the computations described above. That may comprise retrieving the feature volume from a memory where that data has been stored following its creation, or, as another example, that may comprise accessing that data when extracted from a stream of transmitted data. Next, these teachings provide for taking a point of interest 302 inside the subspace described above and using that point of interest in combination with the feature volume to obtain an interpolated feature vector 303 for this point. The feature vector obtained in the previous step can then be passed to the field regressor function 304 to determine the field value(s) 305 for the query point.

In that way, a representation of the original uncompressed data can be retrieved, readily and quickly, from the compressed version thereof.

These teachings accordingly will be understood to describe an approach to encoding spatial as well as spatio-temporal data, targeting 3-dimensional scalar or vector fields specifically and, optionally, their evolution in time. That said, there is no limitation against applying the approaches described herein to any other number of dimensions. These approaches provide lossy compression by exploiting spatial patterns in data using machine learning but does so in a way that eliminates or at least drastically reduces the aforementioned problems of transmission, storage, bandwidth, and RAM/VRAM capacities as well as processing capabilities, thus allowing their use in real-time applications at large.

Those skilled in the art will recognize that a wide variety of modifications, alterations, and combinations can be made with respect to the above-described embodiments without departing from the scope of the invention, and that such modifications, alterations, and combinations are to be viewed as being within the ambit of the inventive concept.

What is claimed is:

1. A data compression apparatus comprising;
memory having data to be compressed comprising at least one of spatial data and spatio-temporal data stored therein;
a control circuit operably coupled to the memory and configured to:
access the data to be compressed in the memory;
compress the data to be compressed to provide compressed data by:
subdivide the data to be compressed into a plurality of subspaces;
use an initialization scheme to construct at least one compressed representation.

2. The data compression apparatus of claim 1 wherein the data to be compressed comprises single channel three-dimensional volume data.

3. The data compression apparatus of claim 1 wherein the data to be compressed comprises a plurality of multiple channels of temporal volumetric data.

4. The data compression apparatus of claim 1 wherein the compressed data has an SDF quality average of at least 0.96 as measured by the F1 metric in points near the surface and 0.0006 MAE (mean absolute error) measured in points throughout the volume.

5. The data compression apparatus of claim 1 wherein the data to be compressed comprises data of Signed Distance Fields (SDF) and wherein the compressed data represents an average compression ratio exceeding ×15 as compared to a volumetric grid of field's values needed to achieve the same quality.

6. The data compression apparatus of claim 1 wherein the data to be compressed comprises visual effects (VFX) data and wherein the compressed data represents an average compression ratio exceeding ×10 and compression quality of at least 40 as measured with PSNR.

7. The data compression apparatus of claim 1 wherein the optimization algorithm employs, at least in part, gradient descent.

8. The data compression apparatus of claim 1 wherein the control circuit is further configured to:
use an optimization algorithm to optimize at least one of the compressed representation and parameters of a function that retrieves original data from the compressed representation by minimizing errors between predicted and actual results to thereby identify sets of parameters that each represent a corresponding one of the plurality of subspaces.

9. The data compression apparatus of claim 1 wherein the control circuit is further configured to:
use an optimization algorithm to optimize both the compressed representation and parameters of a function that retrieves original data from the compressed representation by minimizing errors between predicted and actual results to thereby identify sets of parameters that each represent a corresponding one of the plurality of subspaces.

10. The data compression apparatus of claim 1 wherein the control circuit is further configured to:
use a function to recover original data from the compressed representation, wherein the function comprises at least one of a parametrized function and a non-parametrized function.
